(19) United States
(12) Patent Application Publication
(10) Pub. No.: US 2025/0240947 A1
(43) Pub. Date: Jul. 24, 2025

(54) SEMICONDUCTOR STRUCTURE INCLUDING A BIT LINE STRUCTURE AND METHOD OF MANUFACTURING THE SAME

(71) Applicant: NANYA TECHNOLOGY CORPORATION, NEW TAIPEI CITY (TW)

(72) Inventor: HSU CHIANG, NEW TAIPEI CITY (TW)

(21) Appl. No.: 19/012,993

(22) Filed: Jan. 8, 2025

Related U.S. Application Data
(63) Continuation-in-part of application No. 18/421,042, filed on Jan. 24, 2024.

(51) Int. Cl. H10B 12/00

(52) U.S. Cl. CPC H10B 12/482; H10B 12/315

(57) ABSTRACT

A semiconductor structure and a method of manufacturing the same are provided. The semiconductor structure includes a base structure, a first bit line structure buried in the base structure, a second bit line structure buried in the base structure, and a spacer structure positioned in the base structure. The first bit line structure includes a first main portion and a first cap portion over the first main portion. The first cap portion includes a first lower portion over the first main portion and a first upper portion over the first lower portion. The second bit line structure includes a second main portion and a second cap portion over the second main portion. The spacer structure surrounds the first main portion and the first lower portion of the first cap portion. The spacer structure comprises a first air gap.

### CROSS-REFERENCE TO RELATED APPLICATION

This application is a continuation-in-part application of U.S. Non-Provisional application Ser. No. 18/421,042 filed Jan. 24, 2024, which is incorporated herein by reference in its entirety.

### TECHNICAL FIELD

The present disclosure relates to a semiconductor structure and a method of manufacturing the same, and more particularly, to a semiconductor structure including a bit line structure, and a method of manufacturing the same.

### DISCUSSION OF THE BACKGROUND

Semiconductor structures are used in various electronic applications, and sizes of semiconductor structures are continuously decreasing to meet growing demands for application requirements. However, such scaling down presents challenges that are becoming more frequent and impactful. Decreasing dimensions and pitches of signal lines, such as word lines and bit lines in memory devices like dynamic random-access memory (DRAM) devices, can lead to increased parasitic capacitance, which becomes a critical concern.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor structure. The semiconductor structure includes a base structure; a first bit line structure buried in the base structure; a second bit line structure buried in the base structure; and a spacer structure positioned in the base structure. The first bit line structure comprises a first main portion and a first cap portion over the first main portion. The first cap portion includes a first lower portion over the first main portion and a first upper portion over the first lower portion. The second bit line structure comprises a second main portion and a second cap portion over the second main portion. The spacer structure surrounds the first main portion and the first lower portion of the first cap portion. The spacer structure comprises a first air gap.

Another aspect of the present disclosure provides a semiconductor structure. The semiconductor structure includes a base structure; a first bit line structure buried in the base structure; a second bit line structure buried in the base structure; a first air gap disposed in the base structure; and a second air gap disposed above the base structure. The first bit line structure comprises a first main portion and a first cap portion over the first main portion. The first cap portion includes a first lower portion over the first main portion and a first upper portion over the first lower portion. The second bit line structure comprises a second main portion and a second cap portion over the second main portion. The first air gap surrounds the first main portion and the first lower portion of the first cap portion. The second air gap contacts both the first lower portion of the first cap portion and the first upper portion of the first cap portion.

Another aspect of the present disclosure provides a method of manufacturing a semiconductor structure. The method includes providing a base structure, wherein the base structure includes a base portion and a plurality of active areas in the base portion; forming a plurality of trenches extending into the base portion and the plurality of active areas; forming a plurality of bit line structures in the plurality of trenches; and forming a plurality of cell contacts on some of the plurality of active areas.

Another aspect of the present disclosure provides a method of manufacturing a semiconductor structure. The method includes providing a base structure, wherein the base structure includes a base portion and a plurality of active areas in the base portion; forming a first insulation layer covering the base structure; forming a trench in the first insulation layer, wherein the trench extends in the base portion and the plurality of active areas; forming a bit line structure in the trench, wherein the bit line structure comprises a main portion and a cap portion over the main portion; forming a spacer structure surrounding the bit line structure, wherein the spacer structure includes a sacrificial layer sandwiched between a first dielectric layer and a second dielectric layer; removing the sacrificial layer to form a first air gap between the first dielectric layer and the second dielectric layer; reducing a width of the first air gap; forming a first seal layer to seal the first air gap; and forming a plurality of cell contacts on the plurality of active areas.

The foregoing has outlined rather broadly the features and technical advantages of the present disclosure in order that the detailed description of the disclosure that follows may be better understood. Additional features and advantages of the disclosure are described below, and form the subject of the claims of the disclosure. It should be appreciated by those skilled in the art that the conception and specific embodiments disclosed may be readily utilized as a basis for modifying or designing other structures or processes for carrying out the purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

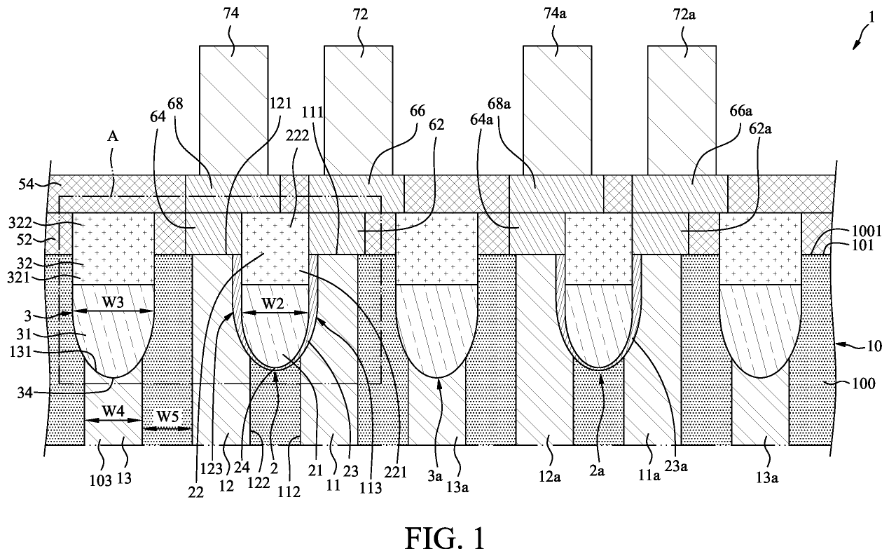

FIG. 1 is a cross-sectional view of a semiconductor structure in accordance with some embodiments of the present disclosure.

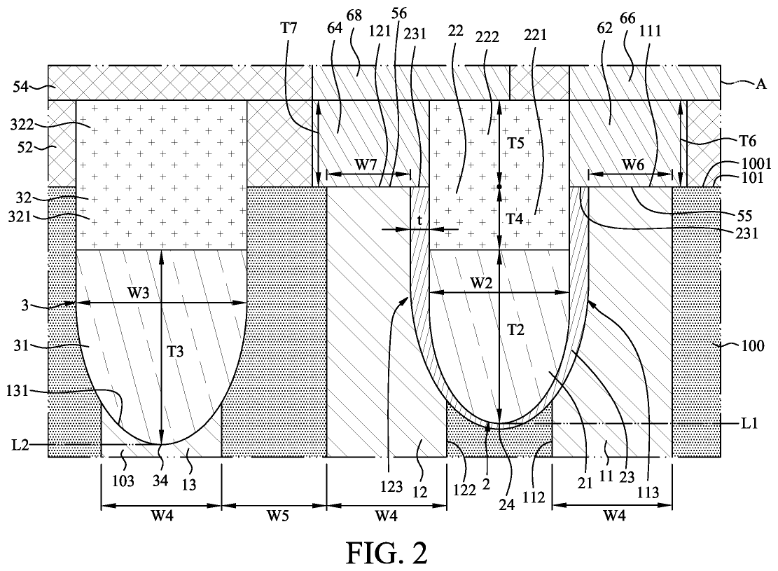

FIG. 2 is an enlarged view of an area “A” in FIG. 1.

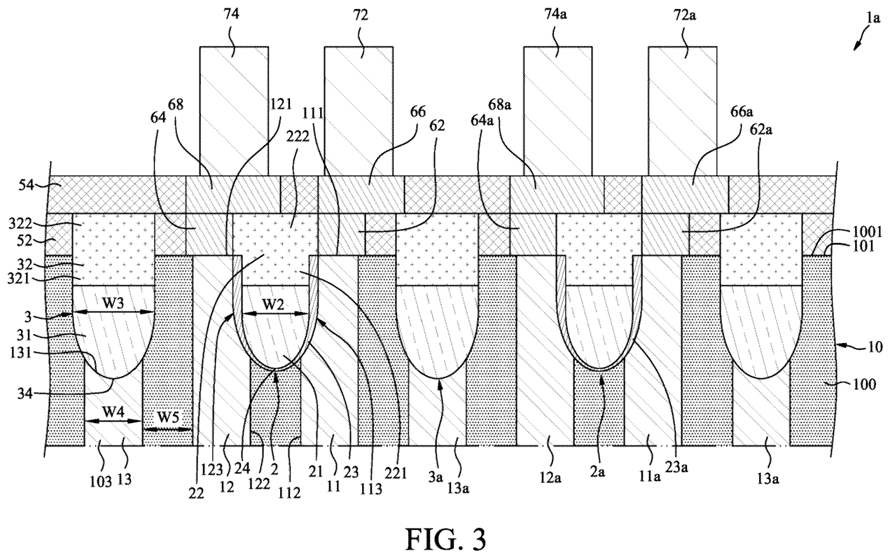

FIG. 3 is a cross-sectional view of a semiconductor structure in accordance with some embodiments of the present disclosure.

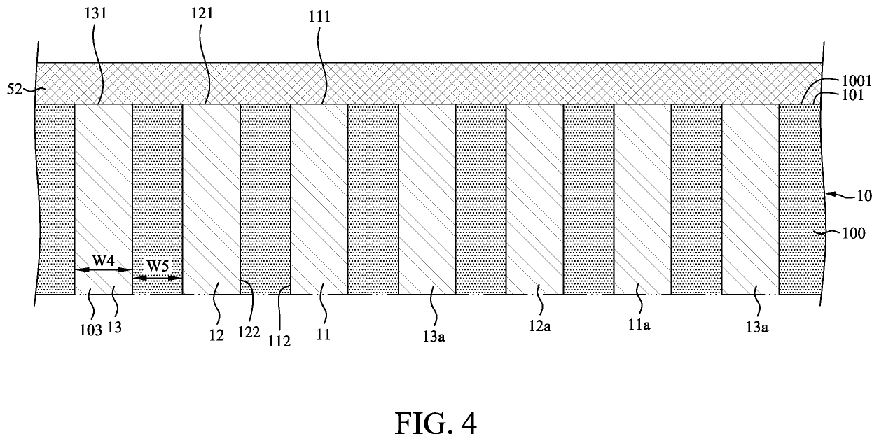

FIG. 4 is a cross-sectional view of one or more stages of an example of a method of manufacturing a semiconductor structure in accordance with some embodiments of the present disclosure.

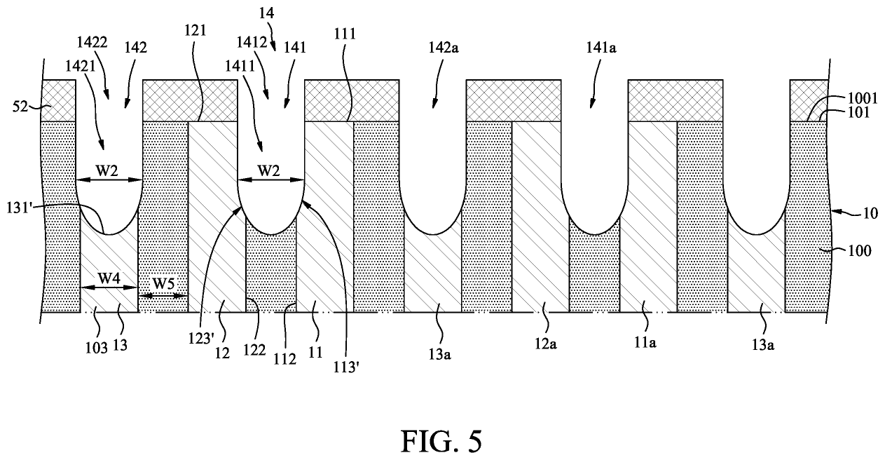

FIG. 5 is a cross-sectional view of one or more stages of an example of a method of manufacturing a semiconductor structure in accordance with some embodiments of the present disclosure.

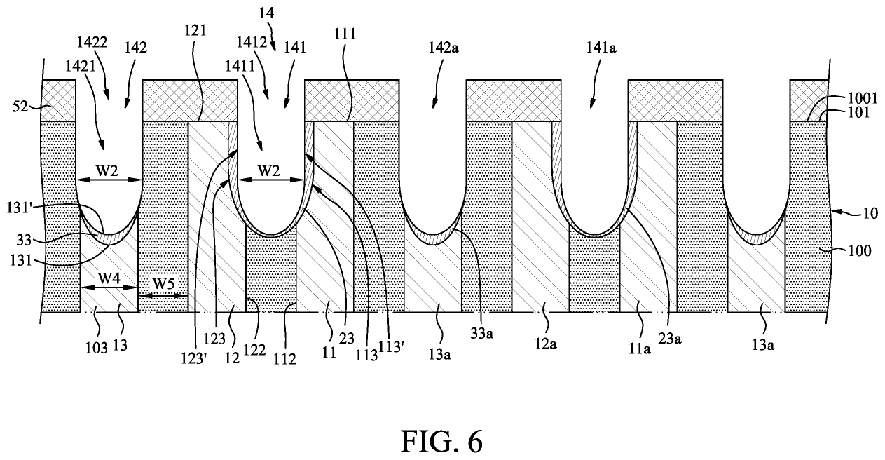

FIG. 6 is a cross-sectional view of one or more stages of an example of a method of manufacturing a semiconductor structure in accordance with some embodiments of the present disclosure.

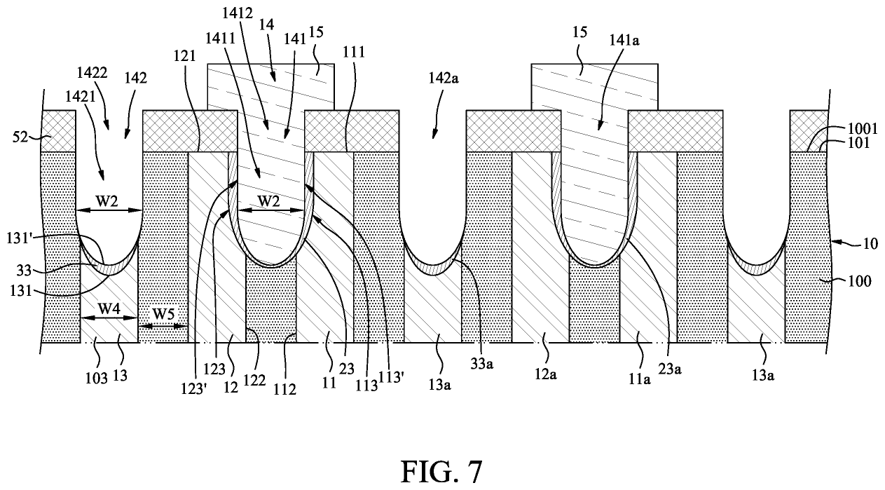

FIG. 7 is a cross-sectional view of one or more stages of an example of a method of manufacturing a semiconductor structure in accordance with some embodiments of the present disclosure.

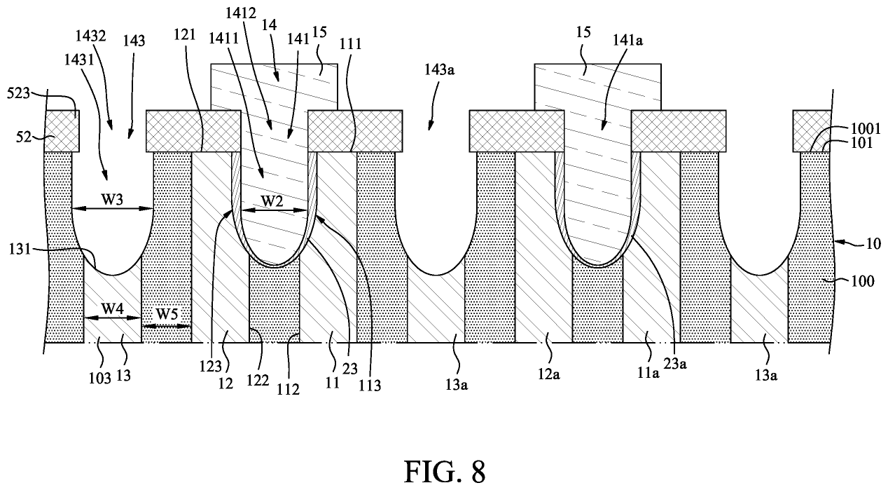

FIG. 8 is a cross-sectional view of one or more stages of an example of a method of manufacturing a semiconductor structure in accordance with some embodiments of the present disclosure.

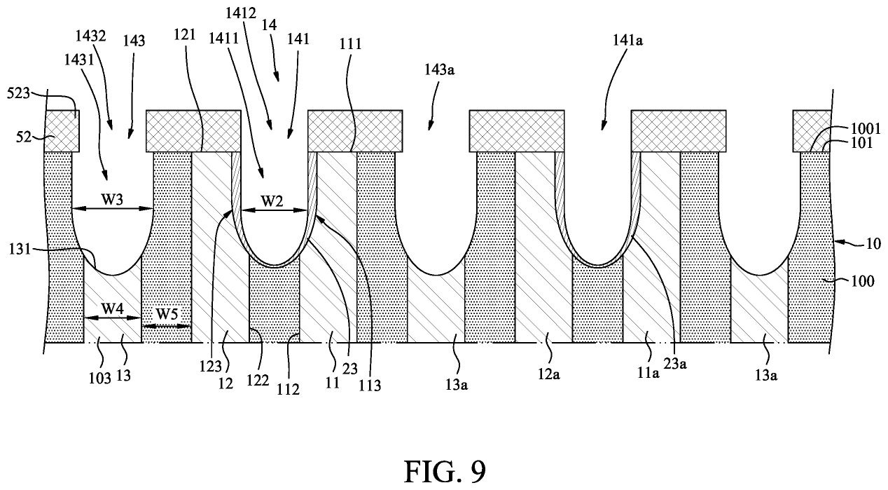

FIG. 9 is a cross-sectional view of one or more stages of an example of a method of manufacturing a semiconductor structure in accordance with some embodiments of the present disclosure.

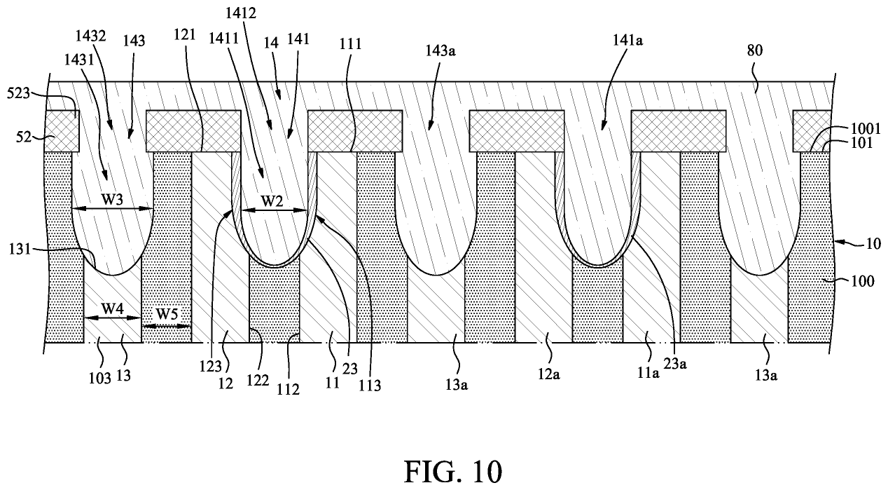

FIG. 10 is a cross-sectional view of one or more stages of an example of a method of manufacturing a semiconductor structure in accordance with some embodiments of the present disclosure.

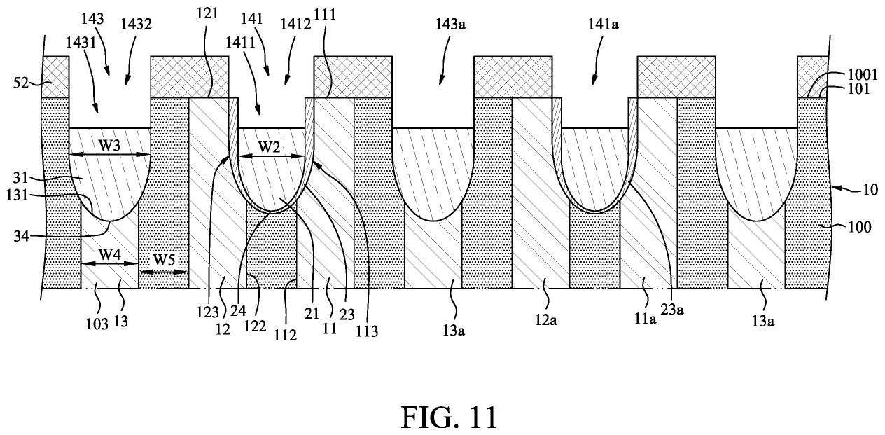

FIG. 11 is a cross-sectional view of one or more stages of an example of a method of manufacturing a semiconductor structure in accordance with some embodiments of the present disclosure.

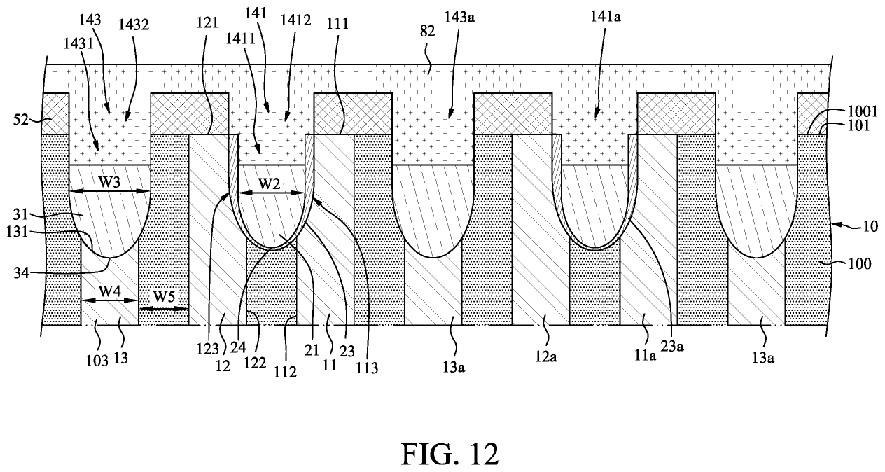

FIG. 12 is a cross-sectional view of one or more stages of an example of a method of manufacturing a semiconductor structure in accordance with some embodiments of the present disclosure.

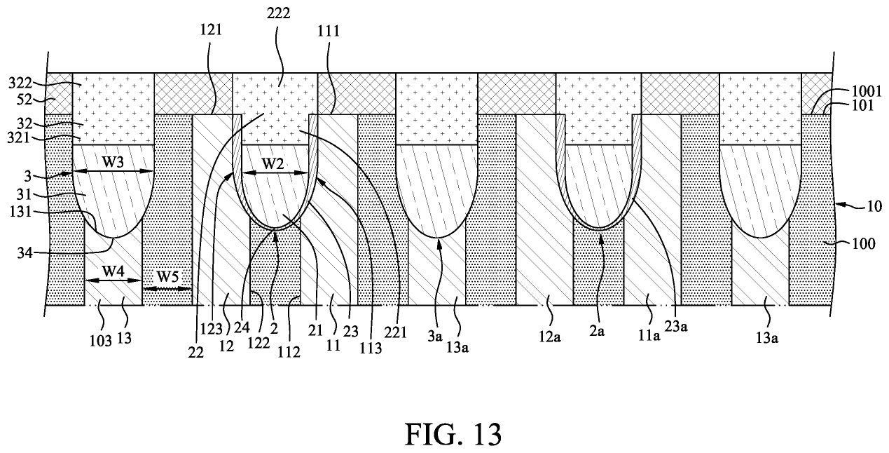

FIG. 13 is a cross-sectional view of one or more stages of an example of a method of manufacturing a semiconductor structure in accordance with some embodiments of the present disclosure.

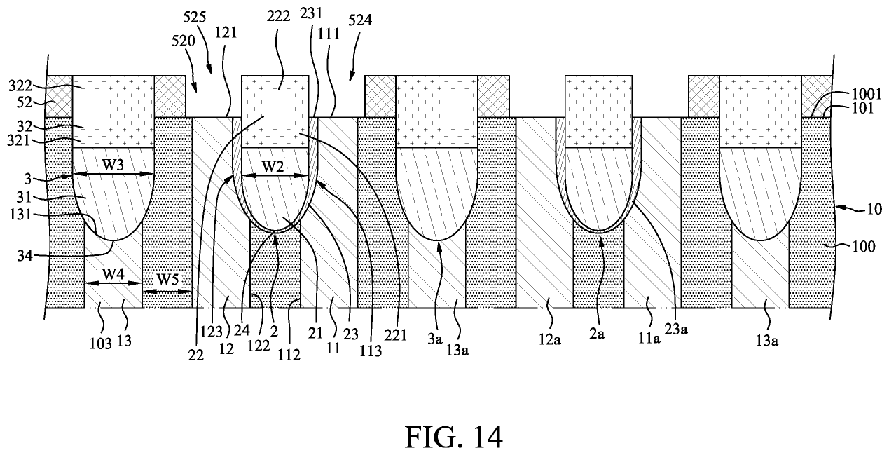

FIG. 14 is a cross-sectional view of one or more stages of an example of a method of manufacturing a semiconductor structure in accordance with some embodiments of the present disclosure.

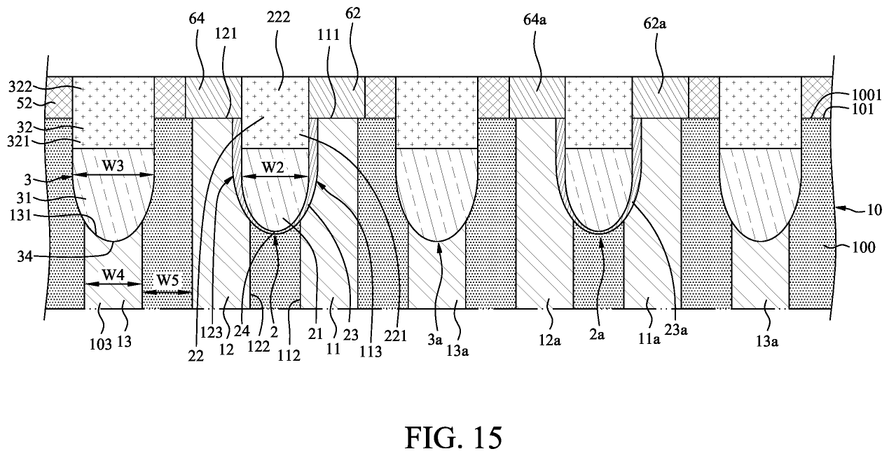

FIG. 15 is a cross-sectional view of one or more stages of an example of a method of manufacturing a semiconductor structure in accordance with some embodiments of the present disclosure.

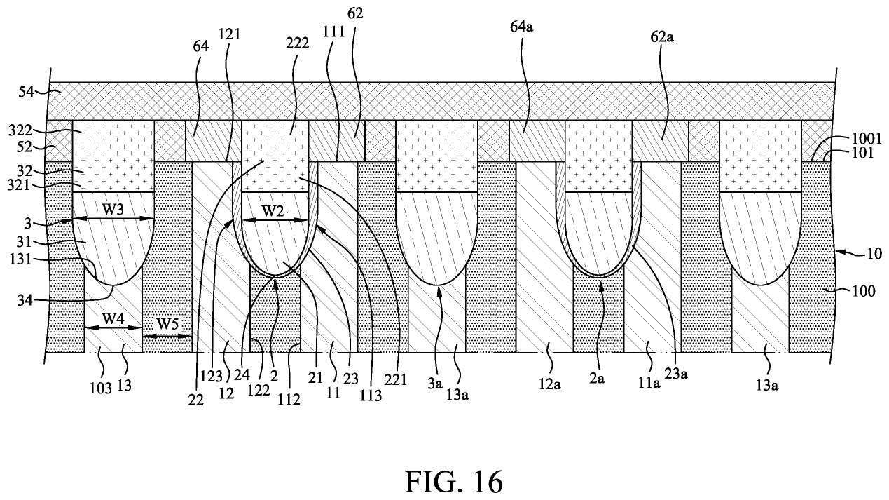

FIG. 16 is a cross-sectional view of one or more stages of an example of a method of manufacturing a semiconductor structure in accordance with some embodiments of the present disclosure.

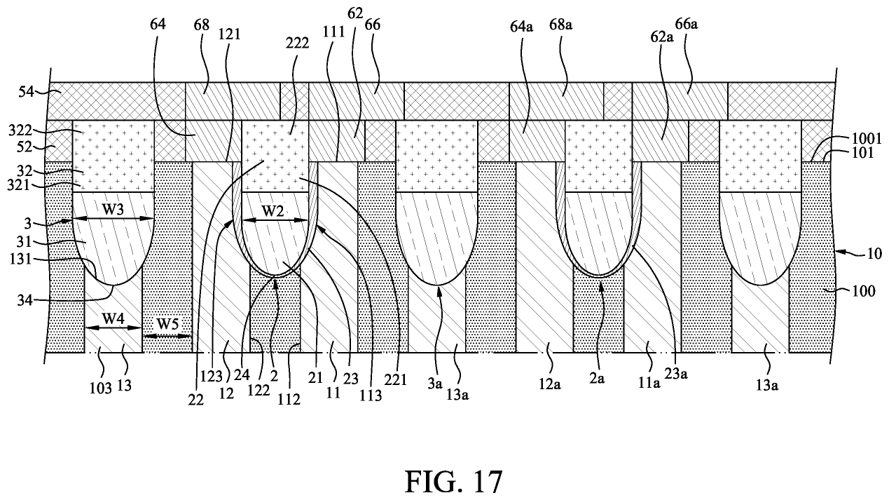

FIG. 17 is a cross-sectional view of one or more stages of an example of a method of manufacturing a semiconductor structure in accordance with some embodiments of the present disclosure.

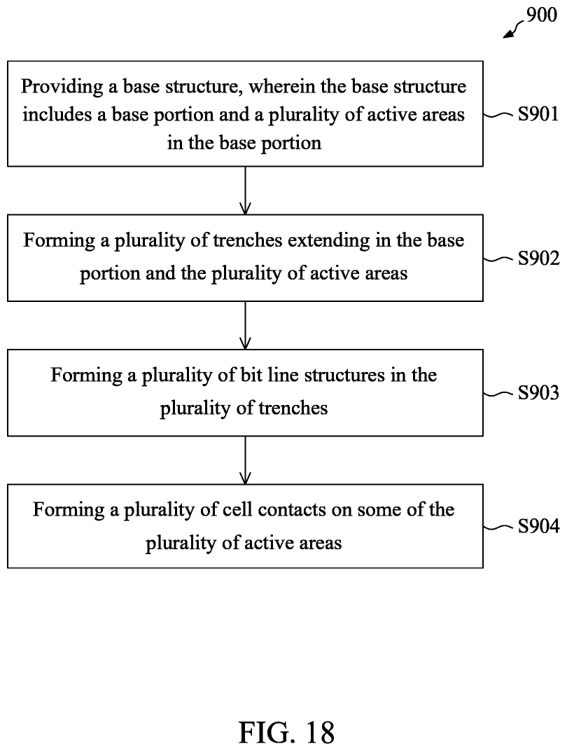

FIG. 18 is a flowchart of a method of manufacturing a semiconductor structure in accordance with some embodiments of the present disclosure.

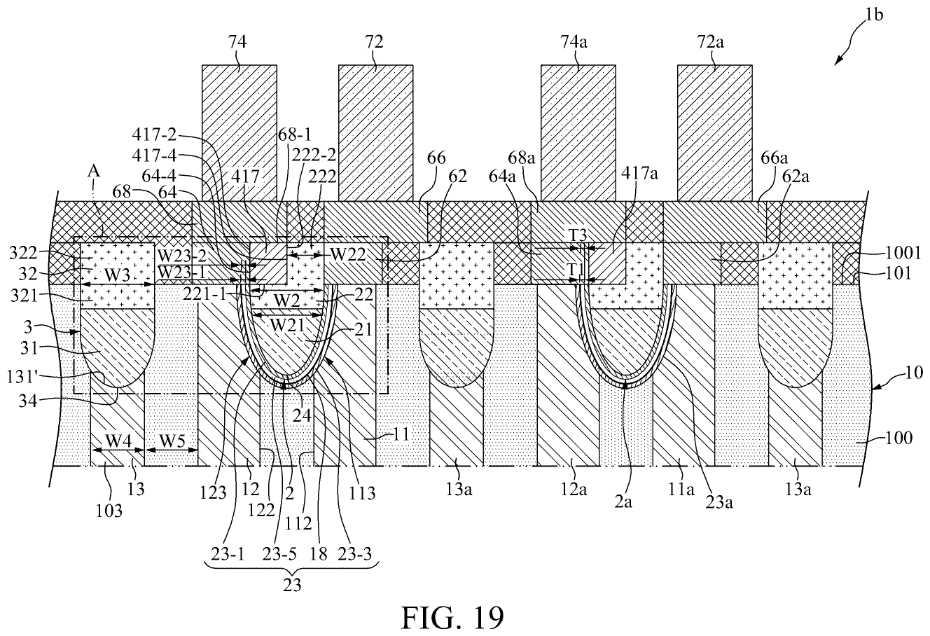

FIG. 19 is a cross-sectional view of a semiconductor structure in accordance with some embodiments of the present disclosure.

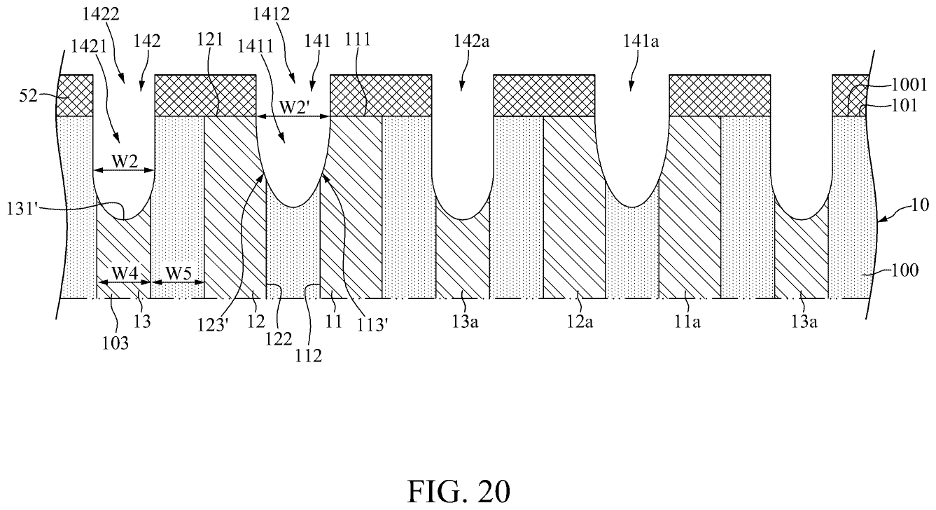

FIGS. 20 to 25 are cross-sectional views of one or more stages of an example of a method of manufacturing a semiconductor structure in accordance with some embodiments of the present disclosure.

### DETAILED DESCRIPTION

Embodiments, or examples, of the disclosure illustrated in the drawings are now described using a specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It should be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It should be understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

FIG. 1 is a cross-sectional view of a semiconductor structure 1 in accordance with some embodiments of the present disclosure. FIG. 2 is an enlarged view of an area “A” in FIG. 1. In some embodiments, the semiconductor structure 1 may be a semiconductor device that includes a circuit, such as a memory cell. Specifically, the memory cell may be a dynamic random-access memory cell (DRAM cell).

In addition, the semiconductor structure 1 may be or include a portion of an integrated circuit (IC) chip that includes various passive and active microelectronic devices, such as resistors, capacitors, inductors, diodes, p-type field-effect transistors (pFETs), n-type field-effect transistors (nFETs), metal-oxide semiconductor field-effect transistors (MOSFETs), complementary metal-oxide semiconductor (CMOS) transistors, bipolar junction transistors (BJTs), laterally-diffused MOS (LDMOS) transistors, high-voltage transistors, high-frequency transistors, fin field-effect transistors (FinFETs), other suitable IC components, or a combination thereof.

The semiconductor structure 1 may include a base structure 10, at least one bit line structure (e.g., a first bit line structure 2, a second bit line structure 3, a third bit line structure 2a, and a fourth bit line structure 3a), at least one spacer 23 and 23a, a first insulation layer 52, at least one cell contact (e.g., a first cell contact 62, a second cell contact 64, a third cell contact 62a, and a fourth cell contact 64a), a second insulation layer 54, at least one landing pad (e.g., a first landing pad 66, a second landing pad 68, a third landing pad 66a, and a fourth landing pad 68a), and at least one conductive structure (e.g., a first conductive structure 72, a second conductive structure 74, a third conductive structure 72a, and a fourth conductive structure 74a).

The base structure 10 may be a substrate and may include a dielectric material, such as an oxide material or a nitride material. Alternatively, the base structure 10 may be a substrate and may include, for example, silicon (Si), germanium (Ge), silicon germanium (SiGe), silicon carbide (SiC), silicon germanium carbide (SiGeC), gallium (Ga), gallium arsenide (GaAs), indium (In), indium arsenide (InAs), indium phosphide (InP), or other IV-IV, III-V, or II-VI semiconductor materials. In some embodiments, the base structure 10 may include a base portion 100 and a plurality of active areas 103 (e.g., a first active area 11, a second active area 12, a third active area 13, a fourth active area 11a, a fifth active area 12a, and a sixth active area 13a) disposed or embedded in the base portion 100.

The base portion 100 may include a dielectric oxide and have a top surface 1001 (e.g., a first surface). Each of the active areas 103 (e.g., the first active area 11, the second active area 12, the third active area 13, the fourth active area 11a, the fifth active area 12a, and the sixth active area 13a) may include silicon (Si) and have a width W4. A portion of the base portion 100 located between the active areas 103 may have a width W5. The width W4 of the active area 103 may be greater than or equal to the width W5 of the portion of the base portion 100 situated between the active areas 103.

In some embodiments, both the third active area 13 and the sixth active area 13a may serve as drain electrodes. Meanwhile, the first active area 11, the second active area 12, the fourth active area 11a and the fifth active area 12a may function as source electrodes.

In some embodiments, as shown in FIG. 1, the base structure 10 may have a top surface 101 (e.g., a first surface). The active areas 103 (e.g., the first active area 11, the second active area 12, the fourth active area 11a and the fifth active area 12a) may be exposed through the top surface 101 (e.g., the first surface) of the base structure 10. The first active area 11 may have a top surface 111 and a lateral surface 112. The top surface 111 of the first active area 11 may be aligned with or coplanar with the top surface 1001 of the base portion 100, and may also be a part of the top surface 101 of the base structure 10. Additionally, the top surface 111 of the first active area 11 may be exposed through the top surface 101 of the base structure 10. The first active area 11 may define an indentation 113 at a corner, which is recessed from both the top surface 111 and the lateral surface 112. The indentation 113 may be configured to accommodate a portion of the first bit line structure 2 and a portion of the spacer 23. The indentation 113 may have a curved sidewall. Furthermore, the first active area 11 may be an asymmetrical structure.

In some embodiments, the second active area 12 includes a top surface 121 and a lateral surface 122. The lateral surface 122 of the second active area 12 faces the lateral surface 112 of the first active area 11. The top surface 121 of the second active area 12 may be aligned with or coplanar with the top surface 1001 of the base portion 100, and may be part of the top surface 101 of the base structure 10. Furthermore, the top surface 121 of the second active area 12 may be exposed through the top surface 101 of the base structure 10.

Additionally, the second active area 12 may feature an indentation 123 at one corner. The indentation 123 is recessed from both the top surface 121 and the lateral surface 122 of the second active area 12. The indentation 123 faces the indentation 113 of the first active area 11 and is designed to accommodate a portion of the first bit line structure 2 and a portion of the spacer 23. The indentation 123 may have a curved sidewall. It should be noted that the second active area 12 is an asymmetrical structure.

In some embodiments, the third active area 13 features a top surface 131 that may be concave and is designed to receive a portion of the second bit line structure 3. The third active area 13 is a symmetrical structure and is separated from the top surface 101 of the base structure 10. As a result, the top surfaces 111, 121, 131 of the active areas 103 (e.g., the first active area 11, the second active area 12 and the third active area 13) are not aligned with one another.

The at least one bit line structure may consist of a plurality of bit line structures, including the first bit line structure 2, the second bit line structure 3, the third bit line structure 2a, and the fourth bit line structure 3a. The first bit line structure 2, the second bit line structure 3, the third bit line structure 2a, and the fourth bit line structure 3a may be buried or embedded in the base structure 10.

The first bit line structure 2 comprises a main portion 21 and a cap portion 22 that is disposed on top of the main portion 21. The main portion 21 may be made of a metal, such as tungsten (W), and the cap portion 22 may consist of an insulation material, such as silicon nitride (SiN). In some embodiments, the main portion 21 may be also referred to as “a bit line structure” or “a bit line”. Additionally, in some embodiments, “the bit line structure” or “the bit line” may comprise the cap portion 22.

The main portion 21 is lower than the top surface 101 (the first surface) of the base structure 10, positioned under the first cell contact 62 and the second cell contact 64. The cap portion 22 extends through the top surface 101 of the base structure 10 and consists of a lower portion 221 and an upper portion 222. The cap portion 22 is a monolithic structure. The lower portion 221 is positioned below the top surface 101 of the base structure 10. The upper portion 222 extends above the lower portion 221 and protrudes above the top surface 101.

The first bit line structure 2 is disposed between the active areas 103 and is electrically insulated from the active areas 103. For example, the first bit line structure 2 is located between the first active area 11 and the second active area 12, and is electrically insulated from the first active area 11 and the second active area 12. In some embodiments, the first bit line structure 2 may laterally overlap the active areas 103, including the first active area 11 and the second active area 12. The first bit line structure 2 may include a bottom end 24. The bottom end 24 may be a bottom end of the main portion 21.

The spacer 23 is positioned around the first bit line structure 2 and is made from an insulation material, such as an oxide material. The spacer 23 is disposed between the first bit line structure 2 and the first active area 11, providing electrical insulation between the first bit line structure 2 and the first active area 11. Similarly, the spacer 23 is positioned between the first bit line structure 2 and the second active area 12, electrically insulating the first bit line structure 2 from the second active area 12.

The spacer 23 may have a top surface 231 that may be aligned with or coplanar with the top surface 101 of the base structure 10. In other words, the top surface 231 of the spacer 23 may be aligned with or coplanar with the top surface 1001 of the base portion 100, the top surface 111 of the first active area 11, and the top surface 121 of the second active area 12.

In some embodiments, the first bit line structure 2 and the spacer 23 may be disposed within the indentation 113 of the first active area 11 and the indentation 123 of the second active area 12. As a result, the first bit line structure 2 and the spacer 23 may extend beyond the lateral surface 112 of the first active area 11 and the lateral surface 122 of the second active area 12.

A shape of the indentation 113 in the first active area 11 and a shape of the indentation 123 in the second active area 12 may conform to a profile of the spacer 23. In some embodiments, the spacer 23 may exhibit a variable thickness t. Specifically, the spacer 23 may taper toward the bottom end 24 of the first bit line structure 2, and the thickness t of the spacer 23 may gradually decrease toward the bottom end 24 of the first bit line structure 2.

The first bit line structure 2 may function as a passive bit line structure. The first bit line structure 2 is characterized by a maximum width W2 that is equal to a maximum width of the main portion 21 and a maximum width of the cap portion 22. The maximum width W2 of the first bit line structure 2 is greater than the width W4 of the first active area 11 and the width W5 of the portion of the base portion 100 disposed between the active areas 103. In some embodiments, the main portion 21 may have a maximum thickness T2, and the lower portion 221 of the cap portion 22 may have a thickness T4 that ranges from 30 nm to 50 nm. The upper portion 222 of the cap portion 22 may also have a thickness T5.

The second bit line structure 3 comprises a main portion 31 and a cap portion 32 positioned atop the main portion 31. The main portion 31 is made of a metal, such as tungsten (W), and the cap portion 32 is made of an insulation material, such as silicon nitride (SiN). In some embodiments, the main portion 31 may also be referred to as “a bit line structure” or “a bit line”. Additionally, in some embodiments, “the bit line structure” or “the bit line” may comprise the cap portion 32.

The main portion 31 is disposed lower than the top surface 101 (e.g., the first surface) of the base structure 10, and lower than the first cell contact 62 and the second cell contact 64. The cap portion 32 extends through the top surface 101 and consists of a lower portion 321 and an upper portion 322. The lower portion 321 is positioned lower than the top surface 101 of the base structure 10, and the upper portion 322 extends above the lower portion 321, effectively protruding beyond the top surface 101 of the base structure 10.

The second bit line structure 3 may be positioned over or on the third active area 13 and is electrically connected to the active areas 103, including the third active area 13. For example, the main portion 31 of the second bit line structure 3 may directly contact the top surface 131 of the third active area 13. Additionally, the second bit line structure 3 may laterally overlap the active areas 103, such as the first active area 11 and the second active area 12. The second bit line structure 3 features a bottom end 34, and the bottom end 34 corresponds to a bottom end of the main portion 31.

The second bit line structure 3 may be positioned without being surrounded by a spacer, meaning that there is no spacer disposed around the second bit line structure 3. Consequently, there is no spacer disposed between the second bit line structure 3 and the third active area 13, allowing for electrical connection between the second bit line structure 3 and the third active area 13. In some embodiments, the second bit line structure 3 may extend beyond two opposite lateral surfaces of the third active area 13. Additionally, a shape of the top surface 131 of the third active area 13 may conform to a profile of the second bit line structure 3.

The second bit line structure 3 may be configured as an active bit line structure. The second bit line structure 3 may have a maximum width W3, which is equal to a maximum width of the main portion 31 and a maximum width of the cap portion 32. In some embodiments, the maximum width W3 of the second bit line structure 3 is greater than the width W4 of the third active area 13 and the width W5 of the portion of the base portion 100 is located between the active areas 103. Additionally, the maximum width W2 of the first bit line structure 2 is less than the maximum width W3 of the second bit line structure 3.

Furthermore, the main portion 31 has a maximum thickness T3. The maximum thickness T3 of the main portion 31 of the second bit line structure 3 may be greater than the maximum thickness T2 of the main portion 21 of the first bit line structure 2. The thickness of the cap portion 32 of the second bit line structure 3 is equal to the thickness of the cap portion 22 of the first bit line structure 2.

In some embodiments, the bottom end 24 of the first bit line structure 2 may be at a level different from a level of the bottom end 34 of the second bit line structure 3. For example, an elevation L1 of the bottom end 24 of the first bit line structure 2 may be higher than an elevation L2 of the bottom end 34 of the second bit line structure 3.

The first insulation layer 52 may be positioned on the top surface 101 of the base structure 10. A material used for the first insulation layer 52 may be same as or different from materials used for the cap portion 22 of the first bit line structure 2 and the cap portion 32 of the second bit line structure 3. For example, the first insulation layer 52 may consist of insulation materials such as silicon nitride (SiN), silicon oxynitride (SiON), or another suitable material.

The cap portion 22 of the first bit line structure 2 and the cap portion 32 of the second bit line structure 3 may extend through the first insulation layer 52. Consequently, a thickness of the first insulation layer 52 may be equal to the thickness T5 of the upper portion 222 of the cap portion 22 of the first bit line structure 2.

The first cell contact 62 may be positioned over the base structure 10 and electrically connected to the first active area 11. A material used for the first cell contact 62 may consist of a conductive material such as titanium (Ti), tungsten (W), or another suitable material. The first cell contact 62 is designed to cover and contact the first active area 11, thereby forming a contact area 55 between the first cell contact 62 and the top surface 111 of the first active area 11. A width W6 of the contact area 55 may be greater than one half of the width W4 of the first active area 11. Additionally, the first cell contact 62 may also cover and contact the top surface 231 of the spacer 23.

The first cell contact 62 may extend through the first insulation layer 52, resulting in a thickness T6 of the first cell contact 62 being equal to a thickness of the first insulation layer 52 and the thickness T5 of the upper portion 222 of the cap portion 22 of the first bit line structure 2. A lateral surface of the first cell contact 62 may contact a lateral surface of the upper portion 222 of the cap portion 22 of the first bit line structure 2. In some embodiments, the main portion 21 of the first bit line structure 2 may be separated from the first cell contact 62 by the lower portion 221 of the cap portion 22 of the first bit line structure 2 and a portion of the spacer 23.

The second cell contact 64 may be positioned over the base structure 10 and electrically connected to the second active area 12. A material used for the second cell contact 64 may consist of a conductive material such as titanium (Ti), tungsten (W), or another suitable material. The second cell contact 64 is designed to cover and contact the second active area 12, thereby forming a contact area 56 between the second cell contact 64 and the top surface 121 of the second active area 12. A width W7 of the contact area 56 may be greater than one half of the width W4 of the second active area 12. Additionally, the second cell contact 64 may cover and contact the top surface 231 of the spacer 23.

The second cell contact 64 may extend through the first insulation layer 52, resulting in a thickness T7 of the second cell contact 64 being equal to the thickness of the first insulation layer 52 and the thickness T5 of the upper portion 222 of the cap portion 22 of the first bit line structure 2. A lateral surface of the second cell contact 64 may contact a lateral surface of the upper portion 222 of the cap portion 22 of the first bit line structure 2. In some embodiments, the main portion 21 of the first bit line structure 2 may be separated from the second cell contact 64 by the lower portion 221 of the cap portion 22 of the first bit line structure 2 and a portion of the spacer 23.

The second insulation layer 54 may be positioned on the first insulation layer 52. A material used for the second insulation layer 54 may be same as or different from a material used for the first insulation layer 52. For example, the second insulation layer 54 may consist of insulation materials such as silicon nitride (SiN), silicon oxynitride (SiON), or another suitable material.

The first landing pad 66 may be positioned on the first insulation layer 52 and electrically connected to the first cell contact 62. A material used for the first landing pad 66 may consist of a conductive material such as titanium (Ti), tungsten (W), or another suitable material. The first landing pad 66 is designed to cover and contact the first cell contact 62. The first landing pad 66 may extend through the second insulation layer 54. Consequently, a thickness of the first landing pad 66 may be equal to the thickness of the second insulation layer 54.

The second landing pad 68 may be positioned on the first insulation layer 52 and electrically connected to the second cell contact 64. A material used for the second landing pad 68 may consist of a conductive material such as titanium (Ti), tungsten (W), or another suitable material. The second landing pad 68 is designed to cover and contact the second cell contact 64 and the upper portion 222 of the cap portion 22 of the first bit line structure 2. Additionally, the second landing pad 68 may extend through the second insulation layer 54, resulting in a thickness of the second landing pad 68 being equal to the thickness of the second insulation layer 54.

The first conductive structure 72 may be positioned on and electrically connected to the first landing pad 66. The first conductive structure 72 may consist of a three-layered structure and function as a capacitance structure. Similarly, the second conductive structure 74 may be disposed on and electrically connected to the second landing pad 68. The second conductive structure 74 may also be a three-layered structure and serve as a capacitance structure.

The third bit line structure 2a may be same as or similar to the first bit line structure 2 and is positioned between the fourth active area 11a and the fifth active area 12a. The spacer 23a may be same as or similar to the spacer 23 and is located around the third bit line structure 2a. Additionally, the fourth bit line structure 3a may be same as or similar to the second bit line structure 3 and is disposed on the sixth active area 13a.

The third cell contact 62a may be same as or similar to the first cell contact 62. The third cell contact 62a may be positioned over the base structure 10 and is designed to cover and contact the fourth active area 11a. The third cell contact 62a may extend through the first insulation layer 52. Similarly, the fourth cell contact 64a may be same as or similar to the second cell contact 64. The fourth cell contact 64a may be positioned over the base structure 10 and is designed to cover and contact the fifth active area 12a. The fourth cell contact 64a may extend through the first insulation layer 52.

The third landing pad 66a may be same as or similar to the first landing pad 66. The third landing pad 66a may be positioned on the first insulation layer 52 and is designed to cover and contact the third cell contact 62a. The third landing pad 66a may extend through the second insulation layer 54. Similarly, the fourth landing pad 68a may be same as or similar to the second landing pad 68. The fourth landing pad 68a may be disposed on the first insulation layer 52 and is designed to cover and contact the fourth cell contact 64a. The fourth landing pad 68a may extend through the second insulation layer 54.

The third conductive structure 72a may be same as or similar to the first conductive structure 72. The third conductive structure 72a may be positioned on and electrically connected to the third landing pad 66a. Additionally, the fourth conductive structure 74a may be same as or similar to the second conductive structure 74. The fourth conductive structure 74a may be disposed on and electrically connected to the fourth landing pad 68a.

In the embodiment illustrated in FIGS. 1 and 2, the bit line structures (e.g., the first bit line structure 2, the second bit line structure 3, the third bit line structure 2a and the fourth bit line structure 3a) are embedded within the base structure 10. As a result, bit line contacts between the bit line structures (e.g., the second bit line structure 3 and the fourth bit line structure 3a) and the active areas 103 (e.g., the third active area 13 and the sixth active area 13a) may be omitted.

Additionally, a thickness of the cell contact (e.g., the first cell contact 62, the second cell contact 64, the third cell contact 62a and the fourth cell contact 64a) may be reduced. Such configuration leads to a shorter electrical path between the bit line structures (e.g., the second bit line structure 3 and the fourth bit line structure 3a) and the conductive structures (e.g., the first conductive structure 72, the second conductive structure 74, the third conductive structure 72a and the fourth conductive structure 74a). Consequently, an electric resistance between the bit line structures and the conductive structures is reduced, resulting in an improved signal margin. Overall, a total height of the semiconductor structure is reduced.

Furthermore, the bit line structures (e.g., the first bit line structure 2, the second bit line structure 3, the third bit line structure 2a and the fourth bit line structure 3a) are embedded within the base structure 10, and the cell contacts (e.g., the first cell contact 62, the second cell contact 64, the third cell contact 62a and the fourth cell contact 64a) are positioned above the base structure 10. This arrangement means that the cell contacts are not located adjacent to the bit line structures. The main portion (e.g., the main portion 21) of the first bit line structure 2 may be separated from the cell contact (e.g., the first cell contact 62 and the second cell contact 64) by a portion (e.g., the lower portion 221) of a cap portion (e.g., the cap portion 22). The increased distance between the main portion (e.g., the main portion 21) of the first bit line structure 2 and the cell contact (e.g., the first cell contact 62) can help reduce parasitic capacitance, further enhancing a signal margin. In some embodiments, the width W6 of the contact area 55 may be greater than one half of the width W4 of the first active area 11. An increase in size of the contact area 55 between the first cell contact 62 and the first active area 11 can further enhance the signal margin.

FIG. 3 is a cross-sectional view of a semiconductor structure 1a in accordance with some embodiments of the present disclosure. The semiconductor structure 1a is similar to the semiconductor structure 1 shown in FIG. 1, except that a width of the upper portion 222 of the cap portion 22 of the first bit line structure 2 in FIG. 3 may be greater than a width of the upper portion 222 of the cap portion 22 of the first bit line structure 2 in FIG. 1. With reference to FIG. 3, the width of the upper portion 222 of the cap portion 22 of the first bit line structure 2 may be greater than the width of the lower portion 221 of the cap portion 22 of the first bit line structure 2. The upper portion 222 of the cap portion 22 may cover and contact the top surface 231 of the spacer 23. The first cell contact 62 may not cover and contact the top surface 231 of the spacer 23.

FIGS. 4 to 17 are cross-sectional views of one or more stages of a method of manufacturing a semiconductor structure 1 in accordance with some embodiments of the present disclosure.

With reference to FIG. 4, a base structure 10 and a first insulation layer 52 disposed over the base structure 10 are provided. The base structure 10 and the first insulation layer 52 may be same as or similar to the base structure 10 and the first insulation layer 52 shown in FIG. 1.

In some embodiments, the base structure 10 includes a base portion 100 and a plurality of active areas 103 (e.g., a first active area 11, a second active area 12, a third active area 13, a fourth active area 11a, a fifth active area 12a, and a sixth active area 13a) embedded within the base portion 100. The base portion 100 may have a top surface 1001 (e.g., a first surface).

The base structure 10 features a top surface 101 (e.g., a first surface). In some embodiments, the first active area 11 has a top surface 111 and a lateral surface 112. The top surface 111 of the first active area 11 may be aligned with or coplanar with the top surface 1001 of the base portion 100 and may also be part of the top surface 101 of the base structure 10. Additionally, the top surface 111 of the first active area 11 may be exposed through the top surface 101 of the base structure 10.

In some embodiments, the second active area 12 has a top surface 121 and a lateral surface 122. The lateral surface 122 of the second active area 12 faces the lateral surface 112 of the first active area 11. The top surface 121 of the second active area 12 may be aligned with or coplanar with the top surface 1001 of the base portion 100 and may also be part of the top surface 101 of the base structure 10. Additionally, the top surface 121 of the second active area 12 may be exposed through the top surface 101 of the base structure 10.

In some embodiments, the third active area 13 has a top surface 131. The top surfaces 111, 121, and 131 of the active areas 103 (e.g., the first active area 11, the second active area 12 and the third active area 13) are aligned with one another. The first insulation layer 52 is disposed on the top surface 101 of the base structure 10 to cover the active areas 103.

With reference to FIG. 5, a plurality of trenches 14 may be formed to extend through the first insulation layer 52 and into the base portion 100 and the plurality of active areas 103. Dimensions and shapes of the trenches 14 may be substantially equal. The trenches 14 may be formed by applying a photoresist layer and conducting an etching process.

The trenches 14 may include a first trench 141, a second trench 142, a third trench 141a and a fourth trench 142a. The first trench 141 consists of a lower portion 1411 and an upper portion 1412, with the lower portion 1411 located in the base structure 10 and the upper portion 1412 extending through the first insulation layer 52. The first trench 141 may have a maximum width W2. The first active area 11 defines an indentation 113′ at a corner, which is recessed from both the top surface 111 and the lateral surface 112 of the first active area 11. Similarly, the second active area 12 defines an indentation 123′ at a corner, recessed from the top surface 121 and the lateral surface 122 of the second active area 12. The indentations 113′ and 123′ may form portions of the lower portion 1411 of the first trench 141, thereby exposing portions of the first active area 11 and the second active area 12.

The second trench 142 may include a lower portion 1421, which is located in the base structure 10, and an upper portion 1422 that extends through the first insulation layer 52. The second trench 142 may have a maximum width W2. The third active area 13 may have a top surface 131′ that is concave and defines a portion of the lower portion 1421 of the second trench 142, thereby exposing a portion of the third active area 13. Additionally, the third trench 141a may be similar to the first trench 141, and the fourth trench 142a may be similar to the second trench 142.

With reference to FIG. 6, portions of the active areas 103 that are exposed in the trenches 14 may undergo an oxidation to form a plurality of oxides on the exposed portions. For example, a first oxide 23 (e.g., a spacer 23) may be formed on the indentation 113′ of the first active area 11 and the indentation 123′ of the second active area 12. Consequently, an indentation 113 of the first active area 11 may be created. The oxidation reaction may occur from the indentation 113′ to the indentation 113, with a shape of the indentation 113 being similar to a shape of the indentation 113′. The indentation 113 serves as an interface between the first oxide 23 and the first active area 11. A distance between the indentation 113′ and the indentation 113 corresponds to a thickness of the first oxide 23.

Meanwhile, an indentation 123 of the second active area 12 may be formed. The oxidation reaction may occur from the indentation 123′ to the indentation 123, with a shape of the indentation 123 being similar to a shape of the indentation 123′. The indentation 123 serves as an interface between the first oxide 23 and the second active area 12. A distance between the indentation 123′ and the indentation 123 corresponds to a thickness of the first oxide 23. Similarly, a third oxide 23a (e.g., a spacer 23a) may be formed on the fourth active area 11a and the fifth active area 12a.

A second oxide 33 may be formed on the top surface 131′ of the third active area 13, resulting in the formation of a new top surface 131. An oxidation reaction may occur from the top surface 131′ to the top surface 131, with a shape of the top surface 131 being similar to a shape of the top surface 131′. The top surface 131 serves as an interface between the second oxide 33 and the third active area 13. A distance between the top surface 131′ and the top surface 131 corresponds to a thickness of the second oxide 33.

With reference to FIG. 7, a photoresist layer 15 may be formed to cover and fill the first trench 141 and the third trench 141a, thereby protecting the spacer 23 (e.g., the first oxide 23) and the spacer 23a during an etching process. The photoresist layer 15 does not cover the second trench 142 and the fourth trench 142a, leaving the second trench 142 and the fourth trench 142a exposed.

With reference to FIG. 8, the second oxide 33 in the second trench 142 and the fourth trench 142a may be completely removed, for example, through an etching process. Concurrently, a portion of the base portion 100 may also be removed. However, the first insulation layer 52 remains intact. As a result, the second trench 142 and the fourth trench 142a are transformed to a second trench 143 and a fourth trench 143a.

The second trench 143 may consist of a lower portion 1431 and an upper portion 1432. The lower portion 1431 is located in the base structure 10, while the upper portion 1432 extends through the first insulation layer 52. After the etching process, a maximum width W3 of the lower portion 1431 is greater than the maximum width W2 of the lower portion 1421, while a width of the upper portion 1432 is equal to a width of the upper portion 1422. Consequently, the first insulation layer 52 may feature an overhanging portion 523 over the lower portion 1431. Similarly, after the etching process, a lower portion of the fourth trench 143a is wider than a lower portion of the fourth trench 142a.

With reference to FIG. 9, the photoresist layer 15 may be removed to expose the first trench 141 (with the spacer 23) and the third trench 141a (with the spacer 23a).

With reference to FIG. 10, a conductive material 80 may be deposited to fill the trenches 14 (e.g., the first trench 141, the second trench 143, the third trench 141a, and the fourth trench 143a) and to cover a top surface of the first insulation layer 52. A material of the conductive material 80 may consist of a metal, such as tungsten (W).

With reference to FIG. 11, an upper portion of the conductive material 80 may be removed, for example, through an etching process. A portion of the conductive material 80 may remain in the first trench 141, forming a main portion 21, while another portion of the conductive material 80 may remain in the second trench 143, forming a main portion 31. The top surfaces of both the main portion 21 and the main portion 31 may be lower than the top surface 101 of the base structure 10. Additionally, the overhanging portion 523 (shown in FIG. 10) of the first insulation layer 52, located over the lower portion 1431 of the second trench 143, may be removed during the etching process. As a result, the upper portion 1432 of the second trench 143 may be enlarged to a maximum width W3.

Furthermore, a portion of the first insulation layer 52 located over the spacer 23 may be removed during the etching process. As a result, during the etching process, the upper portion 1412 of the first trench 141 may be enlarged to have a width greater than the maximum width W2. The top surface 231 of the spacer 23 is therefore exposed, and the upper portion of the third trench 141a is also enlarged after the etching process, exposing the top surface of the spacer 23a.

With reference to FIG. 12, an insulation material 82 may be deposited to fill the trenches 14 (e.g., the first trench 141, the second trench 142, the third trench 141a, and the fourth trench 142a) and to contact the main portions 21 and 31, while also covering the top surface of the first insulation layer 52. The insulation material 82 may consist of silicon nitride (SiN) and can be same as or different from the material of the first insulation layer 52.

With reference to FIG. 13, a grinding or polishing process (e.g., a chemical mechanical polishing (CMP)) may be performed on a top surface of the insulation material 82 to remove an upper portion of the insulation material 82 and expose the first insulation layer 52. For example, a portion of the insulation material 82 may remain in the first trench 41, forming a cap portion 22, while another portion of the insulation material 82 may remain in the second trench 42, forming a cap portion 32. As a result, the top surface of the first insulation layer 52 and top surfaces of the cap portions 22 and 32 may be coplanar with each other.

Meanwhile, a plurality of bit line structures (e.g., the first bit line structure 2, the second bit line structure 3, the third bit line structure 2a, and the fourth bit line structure 3a) may be formed in the trenches 14 (e.g., the first trench 141, the second trench 143, the third trench 141a, and the fourth trench 143a). The first bit line structure 2 and the third bit line structure 2a may be formed on the spacers 23 and 23a, respectively.

The first bit line structure 2 may consist of the main portion 21 and the cap portion 22 positioned on the main portion 21. The cap portion 22 includes a lower portion 221 and an upper portion 222. The lower portion 221 is situated lower than the top surface 101 of the base structure 10, while the upper portion 222 extends above the lower portion 221 and protrudes beyond the top surface 101. The first bit line structure 2 is located between the first active area 11 and the second active area 12, and may be electrically insulated from both the first active area 11 and the second active area 12.

The second bit line structure 3 may consist of the main portion 31 and the cap portion 32 positioned on the main portion 31. The cap portion 32 extends through the top surface 101 (e.g., the first surface) of the base structure 10. The cap portion 32 includes a lower portion 321 and an upper portion 322. The lower portion 321 is situated lower than the top surface 101 of the base structure 10, while the upper portion 322 extends above the lower portion 321 and protrudes beyond the top surface 101.

The second bit line structure 3 may be disposed over or on the third active area 13 and may be electrically connected to the third active area 13. For example, the main portion 31 of the second bit line structure 3 may directly contact the top surface 131 of the third active area 13. The second bit line structure 3 is not surrounded by a spacer, that is, there is no spacer between the second bit line structure 3 and the third active area 13. Therefore, the second bit line structure 3 may be electrically connected to the third active area 13.

The maximum width W3 of the second bit line structure 3 may be greater than a width W4 of the third active area 13 and a width W5 of the portion of the base portion 100 located between the active areas 103. The maximum width W2 of the first bit line structure 2 is less than the maximum width W3 of the second bit line structure 3. In some embodiments, a bottom end 24 of the first bit line structure 2 may be at a level different from a level of a bottom end 34 of the second bit line structure 3. For example, a level L1 (as shown in FIG. 2) of the bottom end 24 of the first bit line structure 2 may be higher than a level L2 (as shown in FIG. 2) of the bottom end 34 of the second bit line structure 3.

With reference to FIG. 14, a plurality of openings 520 may be formed to extend through the first insulation layer 52 and to expose top surfaces of some of the active areas 103. In some embodiments, the openings 520 may include a first opening 524 and a second opening 525. The first opening 524 may expose the top surface 111 of the first active area 11 and the top surface 231 of the spacer 23. The second opening 525 may expose the top surface 121 of the second active area 12 and the top surface 231 of the spacer 23.

With reference to FIG. 15, a conductive material may be formed or disposed in the openings 520 to create a plurality of cell contacts (e.g., a first cell contact 62, a second cell contact 64, a third cell contact 62a, and a fourth cell contact 64a) on some of the plurality of active areas 103. The first cell contact 62 may cover and contact the first active area 11 and the top surface 231 of the spacer 23 and may extend through the first insulation layer 52. A lateral surface of the first cell contact 62 may contact a lateral surface of the upper portion 222 of the cap portion 22 of the first bit line structure 2.

The second cell contact 64 may cover and contact the second active area 12 and the top surface 231 of the spacer 23 and may extend through the first insulation layer 52. A lateral surface of the second cell contact 64 may contact a lateral surface of the upper portion 222 of the cap portion 22 of the first bit line structure 2.

The third cell contact 62a may be same as or similar to the first cell contact 62, and covers and contacts the fourth active area 11a while extending through the first insulation layer 52. Similarly, the fourth cell contact 64a may be same as or similar to the second cell contact 64, and covers and contacts the fifth active area 12a while extending through the first insulation layer 52.

With reference to FIG. 16, a second insulation layer 54 may be formed or deposited on the first insulation layer 52 to cover the cap portions 22 and 32 and the cell contacts (e.g., the first cell contact 62, the second cell contact 64, the third cell contact 62a and the fourth cell contact 64a).

With reference to FIG. 17, a plurality of landing pads (e.g., a first landing pad 66, a second landing pad 68, a third landing pad 66a, and a fourth landing pad 68a) may be formed in the second insulation layer 54 to contact the cell contacts (e.g., the first cell contact 62, the second cell contact 64, the third cell contact 62a and the fourth cell contact 64a) respectively.

Subsequently, a plurality of conductive structures (e.g., a first conductive structure 72, a second conductive structure 74, a third conductive structure 72a and a fourth conductive structure 74a) may be formed or deposited on the landing pads (e.g., the first landing pad 66, the second landing pad 68, the third landing pad 66a and the fourth landing pad 68a) to complete the semiconductor structure 1 as shown in FIGS. 1 and 2.

FIG. 18 is a flowchart of a method 900 of manufacturing a semiconductor structure in accordance with some embodiments of the present disclosure.

In some embodiments, the method 900 can include a step S901, in which a base structure is provided, wherein the base structure includes a base portion and at least one active area in the base portion. For example, as shown in FIG. 4, a base structure 10 is provided. The base structure 10 includes a base portion 100 and at least one active area 103, 11, 12, 13, 11a, 12a and 13a in the base portion 100.

In some embodiments, the method 900 can include a step S902, in which a plurality of trenches are formed, wherein the trenches extend into the base portion and the plurality of active areas. For example, as shown in FIG. 5, the trenches 14 may be formed to extend into the base portion 100 and the active areas 103, 11, 12, 13, 11a, 12a and 13a.

In some embodiments, the method 900 can include a step S903, in which a plurality of bit line structures are formed in the plurality of trenches. For example, as shown in FIG. 13, the bit line structures 2, 3, 2a, and 3a may be formed in the trenches 14.

In some embodiments, the method 900 can include a step S904, in which a plurality of cell contacts are formed on some of the plurality of active areas. For example, as shown in FIG. 15, the cell contacts 62, 64, 62a, and 64a may be formed on the first active area 11, the second active area 12, the fourth active area 11a and the fifth active area 12a.

FIG. 19 is a cross-sectional view of a semiconductor structure 1b in accordance with some embodiments of the present disclosure. The semiconductor structure 1b depicted in FIG. 19 is similar to the semiconductor structure 1 shown in FIG. 1, except that spacers 23 and 23a of the semiconductor structure 1b may each comprise an air gap, and air gaps 417 and 417a are formed in the semiconductor structure 1b. The spacer 23a and the air gap 471a are same as or similar to the spacer 23 and the air gap 471, respectively, and repeated descriptions are omitted.

With reference to FIG. 19, the spacer 23 includes a first dielectric layer 23-1, a second dielectric layer 23-3 below the first dielectric layer 23-1, and an air gap 23-5 between the first dielectric layer 23-1 and the second dielectric layer 23-3. In other words, the air gap 23-5 is sandwiched between the first dielectric layer 23-1 and the second dielectric layer 23-3. The spacer 23 may be formed in the location previously occupied by the spacer 23 in FIG. 1 and have a U-shaped profile. In some embodiments, materials of the first dielectric layer 23-1 and the second dielectric layer 23-3 are different. In some embodiments, the first dielectric layer 23-1 and the second dielectric layer 23-3 may comprise a same material. For example, in some embodiments, the first dielectric layer 23-1 and the second dielectric layer 23-3 are made of nitride (e.g., silicon nitride). In other embodiments, the first dielectric layer 23-1 and the second dielectric layer 23-3 are made of oxide (e.g., silicon oxide). In some embodiments, a thickness of the first dielectric layer 23-1 is between 5.5 and 12 nanometers, while a thickness of the second dielectric layer 23-3 is between 4.0 and 8.5 nanometers.

In some embodiments, the spacer 23 further consists of a spacer layer 18 conformally deposited over the second dielectric layer 23-3. In some embodiments, the spacer layer 18 and the second dielectric layer 23-3 are made of a same material, such that there may be no distinct interface between the spacer layer 18 and the second dielectric layer 23-3. A thickness of the spacer layer 18 may be between 0.5 and 2 nanometers. After a deposition of the spacer layer 18, the air gap 23-5 may have a width W23-2 that is less than the width W23-1 of the air gap 23-5 prior to the deposition. Specifically, the width W23-1 of the air gap 23-5 may be reduced by 0.5 to 2 nanometers.

With reference to FIG. 19, the air gap 417 may be disposed between the second landing pad 68 and the main portion 21, adjacent to the upper portion 222 of the cap portion 22. It should be noted that, with respect to the cap portion 22 in FIG. 1, the cap portion 22 consists of the lower portion 221 and the upper portion 222, with the upper portion 222 having a width W22 less than a width W21 of the lower portion 221. In some embodiments, the width W22 of the upper portion 222 of the cap portion 22 may be less than the maximum width W2 of the first bit line structure 2. A top surface 222-1 of the upper portion 222 of the cap portion 22 is covered by the second insulation layer 54. A top surface 221-1 of the lower portion 221 of the cap portion 22 and a side wall 222-2 of the upper portion 222 of the cap portion 22 may contact the air gap 417. In some embodiments, the air gap 417 is disposed between a bottom surface 68-1 of the second landing pad 68 and the top surface 221-1 of the lower portion 221 of the cap portion 22.

FIGS. 20 to 25 are cross-sectional views of one or more stages of an example of a method of manufacturing the semiconductor structure 1b in accordance with some embodiments of the present disclosure. The method is similar to the method of manufacturing the semiconductor structure 1a in FIG. 1, and repeated descriptions are omitted.

With reference to FIG. 20, the first trench 141 is formed with a maximum width W2′. The maximum width W2′ may be greater than the maximum width W2 of the first trench 141 shown in FIG. 5. In some embodiments, the first trench 141 and the second trench 142 may be formed in different processes. In some embodiments, the first trench 141 may be formed using an isotropic etching process, an anisotropic etching process, or a combination thereof. The third trench 141a is same as or similar to the first trench 141, and repeated descriptions are omitted.

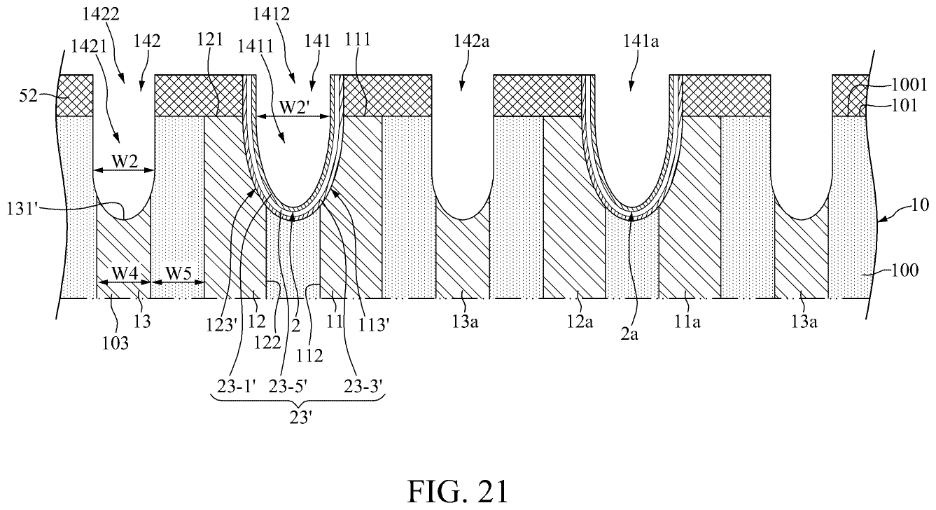

With reference to FIG. 21, a spacer 23′ may be conformally formed within the first trench 141. The spacer 23 consists of a dielectric layer 23-3′ on the first trench 141, a dielectric layer 23-1′ over the dielectric layer 23-3′, and a sacrificial layer 23-5′ sandwiched between the dielectric layer 23-1′ and the dielectric layer 23-3′. The dielectric layer 23-3′ conforms to the trench 141, the sacrificial layer 23-5′ conforms to the dielectric layer 23-3′, and the dielectric layer 23-1′ conforms to the sacrificial layer 23-5′.

A material of the dielectric layer 23-1′ differs from a material of the sacrificial layer 23-5′, and a material of the dielectric layer 23-3′ differs from the material of the sacrificial layer 23-5′. In some embodiments, materials of the dielectric layer 23-1′ and the dielectric layer 23-3′ are different, while in other embodiments, materials of the dielectric layer 23-1′ and the dielectric layer 23-3′ are the same. For example, in some embodiments, the dielectric layer 23-1′ is composed of a nitride (e.g., silicon nitride), the sacrificial layer 23-5′ is made of an oxide (e.g., silicon oxide), and the dielectric layer 23-3′ is composed of a nitride (e.g., silicon nitride). Alternatively, in some embodiments, the dielectric layer 23-1′ is an oxide (e.g., silicon oxide), the sacrificial layer 23-5′ is a nitride (e.g., silicon nitride), and the dielectric layer 23-3′ is an oxide (e.g., silicon oxide).

The dielectric layer 23-1′, the sacrificial layer 23-5′ and the dielectric layer 23-3′ may be sequentially formed within the trench 141 using a deposition process, such as a chemical vapor deposition (CVD) process, and a subsequent planarization process, such as a chemical mechanical polishing (CMP) process, to remove residual portions of deposited materials of the dielectric layer 23-1′, the sacrificial layer 23-5′ and the dielectric layer 23-3′ over a top surface of the first insulation layer 52.

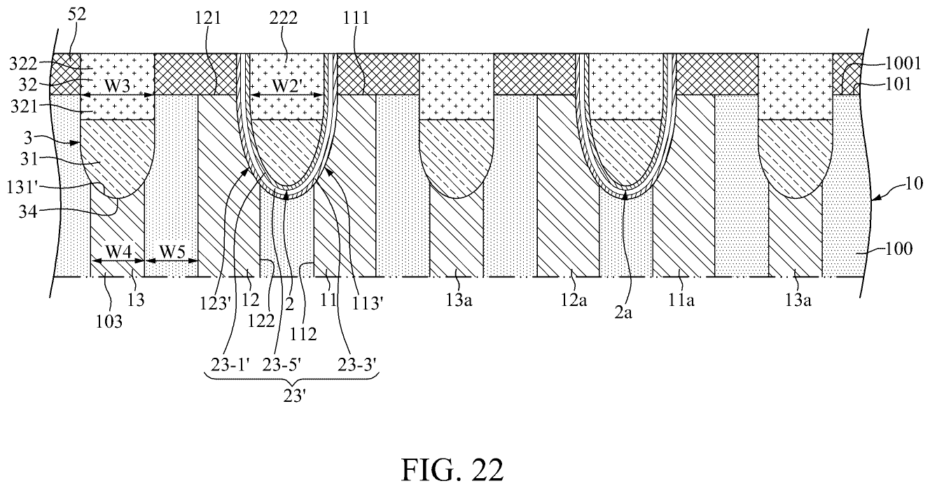

With reference to FIG. 22, a main portion 21 and a cap portion 22 may be sequentially formed in the trench 14 (e.g., the trench 141). A process similar to that illustrated in FIGS. 10 to 13 may be employed to form the main portion 21 and the cap portion 22, and repeated descriptions are omitted.

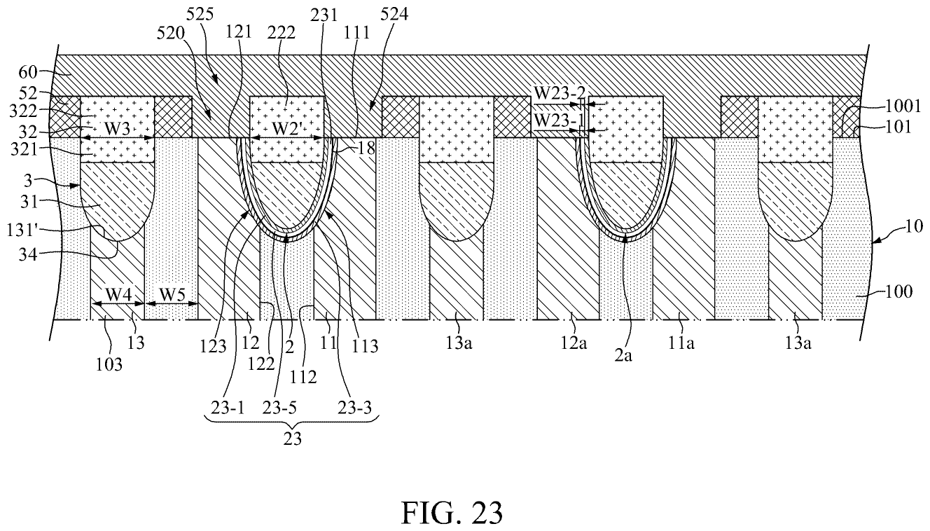

With reference to FIG. 23, the sacrificial layer 23-5′ of the spacer 23′ is removed, creating an air gap 23-5 that is sandwiched between the first dielectric layer 23-1 and the second dielectric layer 23-3. In some embodiments, the sacrificial layer 23-5′ is removed using a vapor etching operation, specifically with vapor-phase hydrogen fluoride (HF). It should be noted that, as shown in FIG. 23, the sacrificial layer 23-5′ of the spacer 23′ is removed after the formation of the second opening 525, which reduces a height of the top surface 231 of the spacer 23. In other embodiments, the sacrificial layer 23-5′ is removed prior to the formation of the second opening 525.

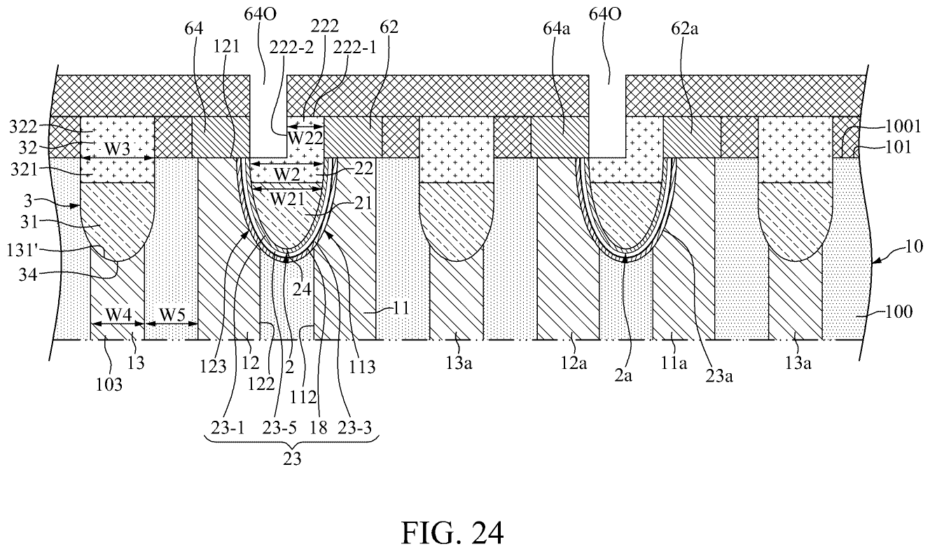

In some embodiments, after the removal of the sacrificial layer 23-5′, a spacer layer 18 may be conformally deposited over the second dielectric layer 23-3. In some embodiments, the spacer layer 18 and the second dielectric layer 23-3 are made of a same material, resulting in no distinct interface between the spacer layer 18 and the second dielectric layer 23-3. A thickness of the spacer layer 18 may be between 0.5 and 2 nanometers. Following the deposition of the spacer layer 18, the air gap 23-5 may have a width W23-2 that is less than a width W23-1 of the air gap 23-5 prior to the deposition; in other words, the width of the air gap is reduced by 0.5 to 2 nanometers. After the formation of the spacer layer 18, a conductive layer 60 may be formed on the first insulation layer 52, on the bit line structures (e.g., the first bit line structure 2, the second bit line structure 3, the third bit line structure 2a and the fourth bit line structure 3a), and in the openings 520. The conductive layer 60 may seal the air gap 23-5. Subsequently, a grinding or polishing process (e.g., a chemical mechanical polishing (CMP)) may be performed on the conductive layer 60 to create a plurality of cell contacts (e.g., a first cell contact 62, a second cell contact 64, a third cell contact 62a, and a fourth cell contact 64a, as shown in FIG. 24) on some of the plurality of active areas 103.

With reference to FIG. 24, following a process similar to that illustrated in FIGS. 15 and 16, a pad etch process is performed to create a pad opening 640. The pad opening 640 may penetrate through the second insulation layer 54 and extend into the cap portion 22. In some embodiments, the pad opening 640 is located in the upper portion 222 of the cap portion 22. Additionally, a bottom surface of the pad opening 640 is aligned with or coplanar with the top surface of the lower portion 221 of the cap portion 22. After the formation of the pad opening 640, a width W22 of the upper portion 222 is less than a width W21 of the lower portion 221. One side wall of the pad opening 640 is coplanar with a side wall of the upper portion 222, while an opposite side wall of the pad opening 640 is coplanar with a side wall of the second cell contact 64.

As shown in FIG. 24, the air gap 23-5 of the spacer 23 is sealed by the second cell contact 64 during a process similar to that shown in FIG. 15.

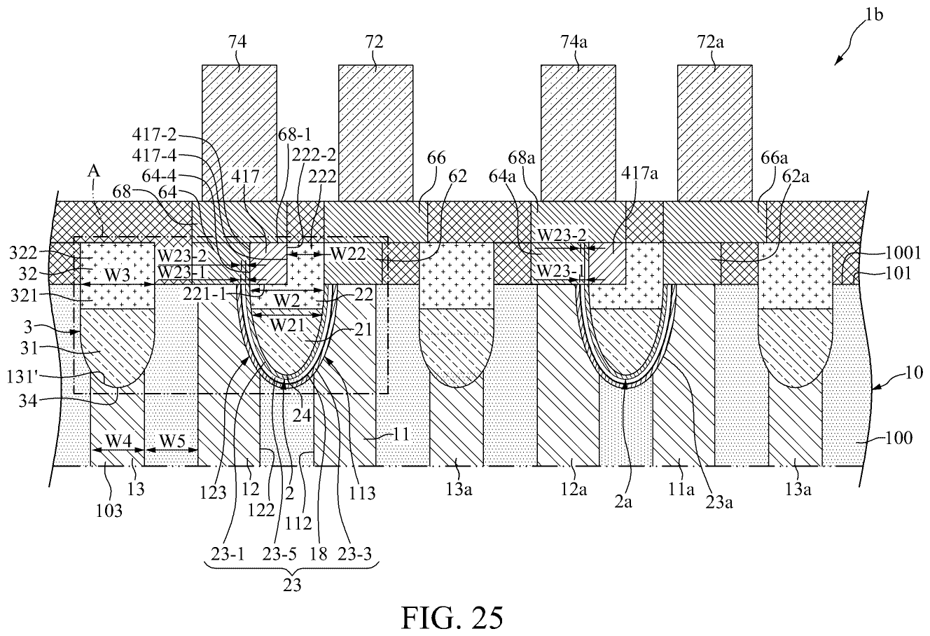

With reference to FIG. 25, the pad opening 640 is sealed by the second landing pad 68, leading to formation of the air gap 417. Following the formation of the air gap 417, the top surface 221-1 of the lower portion 221 of the cap portion 22 and a side wall 222-2 of the upper portion 222 of the cap portion 22 may contact the air gap 417. The air gap 417 is disposed between a bottom surface 68-1 of the second landing pad 68 and the top surface 221-1 of the lower portion 221 of the cap portion 22.

Additionally, the width W22 of the upper portion 222 is less than the width W21 of the lower portion 221. One side wall 417-4 of the air gap 417 is coplanar with the side wall 222-2 of the upper portion 222, and an opposite side wall 417-2 of the air gap 417 is coplanar with the side wall 64-4 of the second cell contact 64.

Following the formation of the spacer 23 and the air gap 417, and subsequent processes similar to the those used in the formation of the semiconductor structure 1 depicted in FIG. 1, a semiconductor structure 1b is achieved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor structure, comprising:
a base structure;
a first bit line structure buried in the base structure, wherein the first bit line structure comprises a first main portion and a first cap portion over the first main portion, and the first cap portion includes a first lower portion over the first main portion and a first upper portion over the first lower portion;
a second bit line structure buried in the base structure, wherein the second bit line structure comprises a second main portion and a second cap portion over the second main portion; and
a spacer structure positioned in the base structure and surrounding the first main portion and the first lower portion of the first cap portion, wherein the spacer structure comprises a first air gap.

2. The semiconductor structure of claim 1, wherein the base structure includes a base portion and a plurality of active areas in the base portion, wherein the first bit line structure is disposed between the plurality of active areas, and the first bit line structure is electrically insulated from the plurality of active areas, wherein the second bit line structure is electrically connected to the plurality of active areas.

3. The semiconductor structure of claim 2, wherein the plurality of active areas include a first active area, a second active area and a third active area, wherein the first bit line structure is disposed between the first active area and the second active area, and the first bit line structure is electrically insulated from the first active area and the second active area, wherein the second bit line structure is electrically connected to the third active area.

4. The semiconductor structure of claim 1, wherein a bottom end of the first bit line structure is at a vertical level different from a vertical level of a bottom end of the second bit line structure.

5. The semiconductor structure of claim 1, wherein a width of the first upper portion of the first cap portion is less than a width of the first lower portion of the first cap portion.

6. The semiconductor structure of claim 1, wherein the second bit line structure is free of being surrounded by the spacer structure.

7. The semiconductor structure of claim 1, wherein the first bit line structure is a passive bit line structure, and the second bit line structure is an active bit line structure.

8. The semiconductor structure of claim 1, wherein the spacer structure further comprises a first dielectric layer surrounding the first main portion and the first lower portion of the first cap portion, and a second dielectric layer conformally disposed below the first dielectric layer, wherein the first air gap is sandwiched between the first dielectric layer and the second dielectric layer.

9. The semiconductor structure of claim 8, wherein the spacer structure further comprises a spacer layer conformally disposed over the second dielectric layer and between the second dielectric layer and the first air gap.

10. The semiconductor structure of claim 8, wherein the first dielectric layer and the second dielectric layer are made of a same material.
